(19) United States
(12) Patent Application Publication
(10) Pub. No.: US 2016/0211351 A1
(43) Pub. Date: Jul. 21, 2016

(54) APPARATUS AND METHOD FOR EPITAXIALLY GROWING SOURCES AND DRAINS OF A FINFET DEVICE

(71) Applicant: INSTITUTE OF MICROELECTRONICS, CHINESE ACADEMY OF SCIENCES, Beijing (CN)

(72) Inventors: Guilei WANG, Beijing (CN); Hushan CUI, Beijing (CN); Huaxiang YIN, Beijing (CN); Junfeng LI, Beijing (CN); Chao ZHAO, Kessel-lo (BE)

(21) Appl. No.: 15/001,087

(22) Filed: Jan. 19, 2016

(30) Foreign Application Priority Data
Jan. 20, 2015 (CN) 201510028853.0
Jan. 20, 2015 (CN) 201520039123.6

(51) Int. Cl. H01L 29/66; H01L 21/02; H01L 21/67; C30B 25/16; C30B 25/08; C30B 25/12; C30B 25/14; H01L 21/306; C23C 16/02

(52) U.S. Cl. CPC H01L 29/66795; H01L 21/30604; H01L 21/02639; H01L 21/67207; C23C 16/0236; C30B 25/08; C30B 25/12; C30B 25/14; C30B 25/16

(57) ABSTRACT

An apparatus and a method for epitaxially growing sources and drains of a FinFET device. The apparatus comprises: a primary chamber; a wafer-loading chamber; a transfer chamber provided with a mechanical manipulator for transferring the wafer; an etching chamber for removing a natural oxide layer on the surface of the wafer and provided with a graphite base for positioning the wafer; at least one epitaxial reaction chamber; a gas distribution device for supplying respective gases to the primary chamber, the wafer loading chamber, the transfer chamber, the etching chamber and the epitaxial reaction chamber; and a vacuum device. The wafer loading, transfer, etching, and epitaxial reaction chambers are all positioned within the primary chamber. The apparatus integrates the etching chamber and epitaxial reaction chamber to remove the natural oxide layer on the surface of the wafer in a condition of isolating water and oxygen before the epitaxial reaction has occurred.

### CROSS-REFERENCE TO RELATED APPLICATION(S)

This application claims priority to a Chinese Patent Application No. 201510028853.0, entitled “APPARATUS AND METHOD FOR EPITAXIAL GROWING SOURCE AND DRAIN OF FINFET DEVICE” and filed on Jan. 20, 2015, and a Chinese Utility Application No. 201520039123.6, entitled “APPARATUS FOR EPITAXIAL GROWING SOURCE AND DRAIN OF FINFET DEVICE” and filed on Jan. 20, 2015, both of which are incorporated herein by reference in their entirety.

### TECHNICAL FIELD

The present disclosure relates to a field for manufacturing a semiconductor device, and particularly to an apparatus and a method for epitaxially growing sources and drains of a FinFET (Fin-field effect transistor) device.

### BACKGROUND

The Fin-FET is a transistor having a FIN-shaped channel, which utilizes several surfaces of a thin Fin as a channel so as to avoid a short channel effect in a conventional transistor and simultaneously increase an operation current.

In a current process for manufacturing the FinFet, in order to increase current mobility to meet a speed requirement of the device, different materials are generally introduced to source and drain regions of NMOS and PMOS transistors so as to introduce a stress to the channel. In general, for a PMOS device, a stress layer of SiGe is epitaxially grown on the source and drain regions of the fin. Since a lattice constant of SiGe is larger than that of Si, the stress layer applies a compressive stress to the channel region. For a NMOS device, a stress layer of Si:C is epitaxially grown on the source and drain regions of the fin. Since a lattice constant of Si:C is smaller than that of Si, the stress layer applies a tensile stress to the channel region.

The epitaxial process is a method for growing a strain material, such as SiGe, Ge, SiC, GeSn and the like, on a semiconductor material. In a process for epitaxially growing the source and drain regions of the FinFet, a thin stress film is selectively epitaxially grown in the source and drain regions of the Fin; and a natural oxide layer of the epitaxial region (exposed silicon region) needs to be removed prior to the epitaxial growth.

An existing method for removing the natural oxide layer primarily comprises a high-temperature baking and a HF(hydrogen fluoride)-last process. When the high-temperature baking is applied for a thicker oxide layer, a longer period is required for the high-temperature (larger than 800 degree) baking, which leads to a larger loss of a silicon fin in a nanometer scale and seriously affects properties of the device. The HF-last process refers to place a wafer in an etching groove or an etching cavity, filled with a diluted HF acid solution having a certain proportion, to remove the natural oxide layer prior to being transferred to an epitaxial reaction chamber.

After the HF-last process is utilized to remove the oxide layer on the surface of the wafer, it is required to move the wafer to the epitaxial reaction apparatus to be epitaxially processed. During the transferring, the wafer contacts oxygen or hydrosphere in air to be re-oxidized to be a natural oxide layer, affecting a reliability of the device.

### SUMMARY

The technical problem to be solved by the present disclosure is to provide an apparatus and a method for epitaxially growing sources and drains of a FinFET device, which effectively avoid formation of the natural oxide layer on the surface of the wafer.

In order to solve the technical problem as mentioned above, the apparatus for epitaxially growing sources and drains of a FinFET device provided by the present disclosure comprises: a primary chamber; at least one wafer loading chamber for loading a wafer; a transfer chamber for transferring the wafer and provided with a mechanical manipulator for transferring the wafer; at least one etching chamber for removing a natural oxide layer on the surface of the wafer and provided with a graphite base for positioning the wafer; at least one epitaxial reaction chamber for the epitaxial reaction; a gas distribution device for supplying respective gases to the primary chamber, the wafer loading chamber, the transfer chamber, the etching chamber and the epitaxial reaction chamber; a vacuum device for vacuumizing the apparatus; wherein the wafer loading chamber, the transfer chamber, the etching chamber and the epitaxial reaction chamber are all positioned within the primary chamber.

Preferably, the apparatus has two wafer loading chambers and two epitaxial reaction chambers.

Preferably, the etching chamber is formed of Teflon.

Preferably, the gas distribution device comprises a first gas distribution device for supplying an inert gas and a second gas distribution device for supplying reaction gases for HF acid.

More preferably, the inert gas is N₂, and the reaction gases for HF acid comprises an anhydrous hydrofluoric gas, diluted gas and catalyze gas in a volume fraction no more than 30%, wherein the diluted gas is N₂ or H₂, and the catalyze gas is an alcohol gas.

Preferably, the vacuum device is a dry pump.

The present disclosure further provides a method for epitaxially growing sources and drains of a FinFET device by the apparatus as mentioned above. The method comprises the following steps of: 1) loading a wafer to the wafer loading chamber and vacuumizing the primary chamber, the wafer loading chamber, the transfer chamber, the etching chamber and the epitaxial reaction chamber; 2) transferring the wafer to the transfer chamber by the mechanical manipulator; 3) transferring the wafer by the mechanical manipulator to the etching chamber to be processed by the HF acid; 4) transferring the wafer to the transfer chamber by the mechanical manipulator; and 5) transferring the wafer to the epitaxial reaction chamber by the mechanical manipulator to grow an epitaxial layer on the wafer.

Preferably, the operation of vacuumizing may be implemented by the following steps: filling a chamber with gas of N₂; vacuumizing the chamber by the vacuumizing device until a pressure within the apparatus is less than or equal to 100 mtorr and maintaining such a vacuum degree for about 60 seconds; and filling the gas of N₂ again to a normal pressure, the operations as mentioned above are repeated for at least three times so that a content of water or oxygen within the respective chambers are less than 1 ppb.

Preferably, a flux of the anhydrous gas for HF acid processing is about 10-100 sccm for about 10-200 seconds at a temperature of about 23-70° C. and a pressure of about 5-150 Torrr. Thus, an etching amount of the natural oxide layer is controlled to be more than 50 angstrom.

Preferably, the method further comprises a step of cleaning the wafer by RCT prior to the step 1).

The apparatus for epitaxially growing sources and drains of a FinFET device provided by the present disclosure integrates the etching chamber and the epitaxial reaction cavity together to remove the natural oxide layer on the surface of the wafer in a condition of isolating water and oxygen before the epitaxial reaction has occurred. Thus, controllability of the epitaxial growing process is enhanced. Since the contact between the water and oxygen as well as the surface of the wafer is better isolated, it avoids regenerating the natural oxide layer on the surface of the wafer, which improves selectivity of the epitaxial growing process and the reliability of the device.

### BRIEF DESCRIPTION OF THE DRAWINGS

FIG. 1 is a schematic view of a configuration of the apparatus for epitaxially growing sources and drains of the FinFET device according to an embodiment of the present disclosure.

The reference numbers are shows as follows: primary chamber 1; wafer loading chamber 2; transferring chamber 3; etching chamber 4; and epitaxial reaction chamber 5.

### DETAILED DESCRIPTION

The above mentioned objects, features and advantages will be easy to be understood by illustrating embodiments of the present disclosure in detail.

In the following description, several details are provided to completely understand the present disclosure. However, the present invention can be implemented by utilizing other embodiments different from the present embodiment illustrated herein. Those skilled in the art may modify the present invention without departing from the scope of the present disclosure and the present invention is not limited to the following particular embodiments.

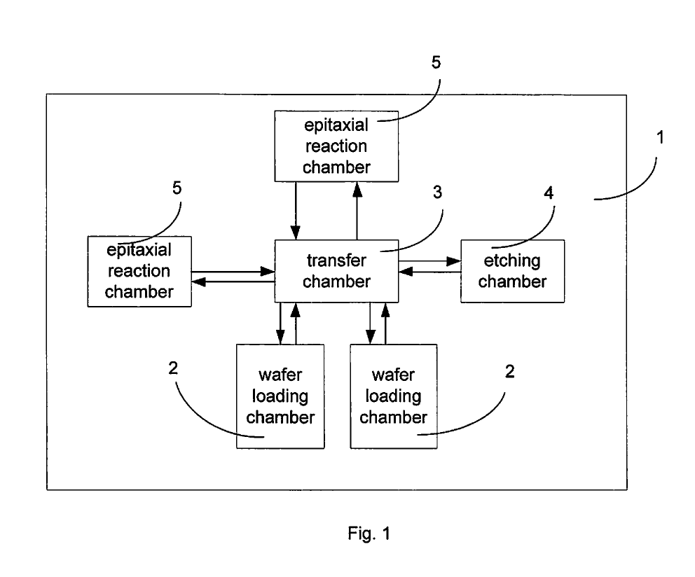

As shown in FIG. 1, the apparatus for epitaxially growing sources and drains of a FinFET device provided by the present disclosure comprises: a primary chamber 1; at least one wafer loading chamber 2 for loading a wafer, wherein it is appreciated for those skilled in the art that the wafer loading chamber 2 is provided with a wafer loading frame on which a wafer is loaded to be epitaxially grown a thin film and in general the number of the wafers may be 1-25; a transfer chamber 3 for transferring the wafer and provided with a mechanical manipulator (not shown) for transferring the wafer, wherein the transferring chamber 3 may be called as a buffer chamber which is an intermediate chamber for the wafer transferred from the other respective chambers so as to be better for HF etching and the epitaxial reaction; at least one etching chamber 4 for removing a natural oxide layer on the surface of the wafer and provided with a graphite base (not shown) for positioning the wafer; at least one epitaxial reaction chamber 6 for the epitaxial reaction, wherein the particular configuration of the epitaxial reaction chamber may be designed according to actual requirement by referring to the existing epitaxial reaction device, and it not limited by the present disclosure; a gas distribution device (not shown) for supplying respective gases to the primary chamber 1, the wafer loading chamber 2, the transfer chamber 3, the etching chamber 4 and the epitaxial reaction chamber 5, wherein it is appreciated by those skilled in the art that the gas distribution device may provide a variety of different gases such as N₂, H₂, anhydrous hydrofluoric gas and the like; a vacuum device (not shown) for vacuumizing the apparatus; wherein the wafer loading chamber 2, the transfer chamber 3, the etching chamber 4 and the epitaxial reaction chamber 5 are all positioned within the primary chamber 1 so as to integrate the respective chambers into the apparatus for epitaxial growing sources and drains of FinFET device.

The apparatus for epitaxially growing sources and drains of a FinFET device provided by the present disclosure integrates the etching chamber 4 and the epitaxial reaction cavity 5 together to remove the natural oxide layer on the surface of the wafer in a condition of isolating water and oxygen before the epitaxial reaction is occurred. Thus, a controllability of the epitaxial growing process is enhanced. Since the contact between the water and oxygen as well as the surface of the wafer is better isolated, it avoids regenerating the natural oxide layer on the surface of the wafer, which improves selectivity of the epitaxial growing process and the reliability of the device.

In order to improve working efficiency of the apparatus, the apparatus has two wafer loading chambers 2 and two epitaxial reaction chambers 2. It is certain that those skilled in the art may select the numbers of the wafer loading chamber 2, the etching chamber 4 and the epitaxial reaction chamber 5 according to actual requirements.

In order to ensure a regular operation of the etching chamber 4, preferably, the etching chamber is formed of Teflon.

In order to ensure a regular supply of the gases, the gas distribution device comprises a first gas distribution device for supplying an inert gas and a second gas distribution device for supplying reaction gases for HF acid. Thus, the gas distribution device may simultaneously meet the requirements of vacuumizing and the HF acid process.

In one preferable embodiment of the present disclosure, the inert gas is N₂, and the reaction gases for HF acid comprises an anhydrous hydrofluoric gas, diluted gas and catalyze gas in a volume fraction no more than 30%. The diluted gas is N₂ or H₂. The catalyze gas is an alcohol gas such as methanol, ethanol and the like.

In order to ensure an effect of vacuumizing, the vacuum device is a dry pump. In one particular embodiment, the gas distribution device and the vacuumizing device may both be integrated into the primary chamber 1.

The present disclosure further provides a method for epitaxially growing sources and drains of a FinFET device by the apparatus as mentioned above. The method comprises the following steps of: 1) loading a wafer to the wafer loading chamber 2 and vacuumizing the primary chamber 1, the wafer loading chamber 2, the transfer chamber 3, the etching chamber 4 and the epitaxial reaction chamber 5 so as to ensure a lower residual amount of water and oxygen in the respective chambers; 2) transferring the wafer to the transfer chamber 3 by the mechanical manipulator; 3) transferring the wafer by the mechanical manipulator to the etching chamber 4 to be processed by the HF acid, the parameters for which may be flexibly selected according to actual requirements; 4) transferring the wafer to the transfer chamber 3 by the mechanical manipulator; and 5) transferring the wafer to the epitaxial reaction chamber by the mechanical manipulator to grow an epitaxial layer on the wafer, the parameters for which may be flexibly selected according to actual requirements. Certainly, it is apparent for those skilled in the art that after the epitaxial reaction is completed, the wafer is transferred to the transfer chamber and then to the wafer loading chamber 2 by the mechanical manipulator to be taken out by an operation staff.

The method for epitaxially growing sources and drains of a FinFET device provided by the present disclosure transfers the wafer within the respective chambers so as to remove the natural oxide layer on the surface of the wafer in a condition of isolating water and oxygen, and implements the epitaxial reaction rapidly. Such a method avoids contacting of the wafer with an external environment and ensures that the natural oxide layer on the surface of the wafer will not be regenerated.

In order to ensure an effect of vacuumizing, the operation of vacuumizing may be implemented by the following steps: filing a gas of N₂; vacuumizing the chamber by the vacuumizing device until a pressure within the apparatus is less than or equal to 100 mtorr and maintaining such a vacuum degree for about 60 seconds; and filling the gas of N₂ again to a normal pressure, the operations as mentioned above are repeated for at least three times so that a content of water or oxygen within the respective chambers are less than 1 ppb.

In order to ensure an effect of removing the natural oxide layer on the surface of the wafer, a flux of the anhydrous gas for HF acid processing is about 10-100 sccm for about 10-200 seconds at a temperature of about 23-70° C. and a pressure of about 5-150 Torrr. Thus, an etching amount of the natural oxide layer is controlled to be more than 50 angstrom. In order to effectively remove the natural oxide layer on the silicon surface at the Fin source and drain region in a short time and to reduce loss of dielectric such as silicon oxide and the like in the other region, the reactive gas for HF acid process may be a mixed gas. For example, the reaction gas for the HF acid may comprise an anhydrous hydrofluoric gas, diluted gas and catalyzing gas in a volume fraction no more than 30%, wherein the diluted gas is N₂ or H₂, and the catalyzing gas is an alcohol gas such as methanol, ethanol and the like. By controlling the ratio of the respective gases in the HF-acid reaction gas and the process conditions such as temperature, pressure and the like, it is advantageous to control an etching speed, etching time and exhausting of byproduct of the reaction. In addition, the diluted gas of N₂ or H₂ may be nicely isolated from the wafer so as to avoid re-oxidizing.

In one preferable embodiment, the flux of the anhydrous hydrofluoric gas is set at about 25 sccm, the flux of the diluted gas is set at about 150 sccm; and the temperature of the reaction chamber is set at about 50° C. and the pressure within the reaction chamber is set at about 50 Torr. In such a process condition, the etching rate for the natural oxide layer is at about 15-25 angstrom/second, and the time for etching is set at about 60 seconds.

In order to remove contamination on a surface of the wafer, the method may further comprise an RCA cleaning of the wafer prior to the step 1). In particular, the wafer is firstly cleaned by SPM (H₂SO4/H₂O₂/H₂O) so as to remove contamination containing carbon (such as organic residue and the like) on the surface of the wafer, followed by a cleaning of SC2 (HCl/H₂O₂/H₂O) so as to remove a trace amount of metal particles on the surface of the wafer and finally a drying by a centrifugal dry machine.

Although the present invention is illustrated in conjunction with the embodiments as mentioned above, it is not limited to the embodiments, but is only limited by the appended claims. Those skilled in the art may easily make modifications and changes without departing from the substantial concept and scope of the present invention.

I/We claim:

1. An apparatus for epitaxially growing sources and drains of a FinFET device, comprising:
a primary chamber;
at least one wafer loading chamber for loading a wafer;
a transfer chamber for transferring the wafer, provided with a mechanical manipulator for transferring the wafer;
at least one etching chamber for removing a natural oxide layer on the surface of the wafer, provided with a graphite base for positioning the wafer;
at least one epitaxial reaction chamber for the epitaxial reaction;
a gas distribution device for supplying respective gases to the primary chamber, the wafer loading chamber, the transfer chamber, the etching chamber and the epitaxial reaction chamber;
a vacuum device for vacuumizing the apparatus;
wherein the wafer loading chamber, the transfer chamber, the etching chamber and the epitaxial reaction chamber are all positioned within the primary chamber.

2. The apparatus for epitaxially growing sources and drains of a FinFET device according to claim 1, wherein the apparatus has two wafer loading chambers and two epitaxial reaction chambers.

3. The apparatus for epitaxially growing sources and drains of a FinFET device according to claim 1, wherein the etching chamber is formed of Teflon.

4. The apparatus for epitaxially growing sources and drains of a FinFET device according to claim 1, wherein the gas distribution device comprises a first gas distribution device for supplying an inert gas and a second gas distribution device for supplying reaction gases for HF acid.

5. The apparatus for epitaxially growing sources and drains of a FinFET device according to claim 1, wherein the inert gas is N₂, and the reaction gases for HF acid comprises an anhydrous hydrofluoric gas, diluted gas and catalyzing gas in a volume fraction no more than 30%, wherein the diluted gas is N₂ or H₂, and the catalyzing gas is an alcohol gas.

6. The apparatus for epitaxially growing sources and drains of a FinFET device according to claim 1, wherein the vacuum device is a dry pump.

7. A method for epitaxially growing sources and drains of a FinFET device, by an apparatus for epitaxially growing sources and drains of a FinFET device, the apparatus comprising:
a primary chamber;
at least one wafer loading chamber for loading a wafer;
a transfer chamber for transferring the wafer, provided with a mechanical manipulator for transferring the wafer;
at least one etching chamber for removing a natural oxide layer on the surface of the wafer, provided with a graphite base for positioning the wafer;
at least one epitaxial reaction chamber for the epitaxial reaction;
a gas distribution device for supplying respective gases to the primary chamber, the wafer loading chamber, the transfer chamber, the etching chamber and the epitaxial reaction chamber;
a vacuum device for vacuumizing the apparatus;
wherein the wafer loading chamber, the transfer chamber, the etching chamber and the epitaxial reaction chamber are all positioned within the primary chamber,
the method comprising the following steps of:
1) loading a wafer into the wafer loading chamber and vacuumizing the primary chamber, the wafer loading chamber, the transfer chamber, the etching chamber and the epitaxial reaction chamber;
2) transferring the wafer to the transfer chamber by the mechanical manipulator;
3) transferring the wafer by the mechanical manipulator to the etching chamber to be processed by the HF acid;
4) transferring the wafer to the transfer chamber by the mechanical manipulator; and
5) transferring the wafer to the epitaxial reaction chamber by the mechanical manipulator to grow an epitaxial layer on the wafer.

8. The method for epitaxially growing sources and drains of a FinFET device according to claim 7, wherein the operation of vacuumizing is implemented by the following steps:
filing a gas of N₂;
vacuumizing the chamber by the vacuumizing device until a pressure within the apparatus is less than or equal to 100 mtorr and maintaining such a vacuum degree for about 60 seconds; and
filling the gas of N₂ again to a normal pressure,
the operations as mentioned above are repeated at least three times so that a content of water or oxygen within the respective chambers are less than 1 ppb.

9. The method for epitaxially growing sources and drains of a FinFET device according to claim 7, wherein a flux of the anhydrous gas for HF acid processing is about 10-100 sccm for about 10-200 seconds at a temperature of about 23-70° C. and a pressure of about 5-150 Torrr, so that an etching amount of the natural oxide layer is controlled to be more than 50 angstrom.

10. The method for epitaxially growing sources and drains of a FinFET device according to claim 7, further comprising a step of cleaning the wafer by RCT prior to the step 1).
